(19) United States
(12) Patent Application Publication
(10) Pub. No.: US 2026/0344029 A1
(43) Pub. Date: Oct. 29, 2026

(54) TRANSISTOR MANUFACTURING METHOD AND ELECTRONIC DEVICE

(71) Applicant: BEIJING SUPERSTRING ACADEMY OF MEMORY TECHNOLOGY, Beijing (CN)

(72) Inventors: Huihui Li, Beijing (CN); Bowen Dong, Beijing (CN); Gengfei Li, Beijing (CN); Qi Hu, Beijing (CN); Guilei Wang, Beijing (CN); Chao Zhao, Beijing (CN)

(73) Assignee: BEIJING SUPERSTRING ACADEMY OF MEMORY TECHNOLOGY, Beijing (CN)

(21) Appl. No.: 19/490,326

(22) PCT Filed: Sep. 4, 2023
(86) PCT No.: PCT/CN2023/116807

§ 371 Date: Dec. 4, 2025

(30) Foreign Application Priority Data
Jul. 6, 2023 (CN) 2023108272234

(51) Int. Cl. H10D 84/83; H10D 62/10; H10D 62/832; H10D 84/01; H10P 50/00; H10P 50/24

(52) U.S. Cl. CPC H10D 84/837; H10D 62/122; H10D 84/0128; H10D 84/0135; H10D 84/0151; H10D 84/016; H10P 50/691; H10D 62/832; H10P 50/242

(57) ABSTRACT

The method comprises: stacking a first silicon layer, a silicon germanium layer, and a second silicon layer on a silicon substrate; forming a plurality of columns of first masks on the second silicon layer in a first direction; etching the second silicon layer according to the plurality of columns of first masks, and covering the surfaces of the etched second silicon layer and the plurality of columns of first masks with a first isolation material; etching the silicon substrate, the first silicon layer, the silicon germanium layer, and the second silicon layer according to the plurality of columns of first masks; forming a plurality of columns of second masks in a second direction; etching the first silicon layer, the silicon germanium layer, and the second silicon layer; depositing a gate material in an etching area of the silicon germanium layer; and etching the first isolation material.

### CROSS-REFERENCE TO RELATED APPLICATIONS

The present application is a U.S. National Phase Entry of International PCT Application No. PCT/CN2023/116807 having an international filing date of Sep. 4, 2023, which claims priority to Chinese Patent Application No. 202310827223.4 filed on Jul. 6, 2023 and entitled “Transistor Manufacturing Method and Electronic Device”. The above-identified applications are incorporated by reference herein in their entireties.

### TECHNICAL FIELD

Embodiments of the present application relate to the technical field of semiconductors, in particular to a method for manufacturing a transistor and an electronic device.

Background art Vertical channel transistor is a new type of semiconductor device. Compared with a planar channel transistor, the vertical channel transistor has a small projected area and unlimited channel length.

In related technologies, in the process of depositing the metal gate of the vertical channel transistor, the exposed source/drain is prone to metal contamination which is difficult to remove, and there is a possibility of causing a short circuit between the source/drain and the metal gate.

### SUMMARY

Embodiments of the present application provide a method for manufacturing a transistor and an electronic device, which effectively prevents the source/drain of the transistor from being contaminated by metal during the manufacturing process. The technical solution is as follows.

In one aspect, there is provided a method for manufacturing a transistor, the method including:
Stacking a first silicon layer (301), a silicon germanium layer (302), and a second silicon layer (303) sequentially on a silicon substrate (300), wherein the first silicon layer (301) is in contact with the silicon substrate (300); forming a plurality of columns of first masks (304) on the second silicon layer (303) in a first direction; etching the second silicon layer (303) according to the plurality of columns of first masks (304), and covering surfaces of an etched second silicon layer (303) and the plurality of columns of first masks (304) with a first isolation material (305);
Etching the silicon substrate (300), the first silicon layer (301), the silicon germanium layer (302), and the second silicon layer (303) according to the plurality of columns of first masks (304) to form a plurality of first grooves (306); filling and annealing a metal material in the plurality of first grooves (306) to form a plurality of first silicon pillars (307) in the first direction;
Forming a plurality of columns of second masks (308) on the plurality of first silicon pillars (307) in a second direction; etching the first silicon layer (301), the silicon germanium layer (302), and the second silicon layer (303) according to the plurality of columns of second masks (308); continuing etching the silicon germanium layer (302) on the basis of the grooves obtained by etching; performing silicon epitaxy in part of an etched region of the silicon germanium layer (302), depositing a gate material in a remaining etched region of the silicon germanium layer (302) to form a plurality of second silicon pillars (309), the plurality of second silicon pillars (309) are distributed in an array in the first direction and the second direction;
Etching the first isolation material (305) covered by the plurality of second silicon pillars (309).

In one aspect, there is provided an electronic device including a logic apparatus including a transistor manufactured according to the method for manufacturing a transistor as in any one of the embodiments described above.

The beneficial effects brought by the technical solutions provided by the embodiments of the present application at least include:

By covering the surface of the second silicon layer etched according to the first mask with the first isolation material, the second silicon layer is protected from possible metal contamination on the second silicon layer during subsequent deposition of the gate material, thereby avoiding short circuit between the source/drain and the gate.

### BRIEF DESCRIPTION OF DRAWINGS

In order to more clearly illustrate the technical solutions of the embodiments of the present disclosure, the following is a brief description of the accompanying drawings that need to be used in the description of the embodiments. It will be apparent that the accompanying drawings in the following description are only some embodiments of the present disclosure, for those of ordinary skills in the art, other accompanying drawings can also be obtained from these accompanying drawings without inventive effort.

FIG. 1 is a schematic diagram of a vertical channel transistor according to one or more exemplary embodiments of the present application.

FIG. 2 is a flowchart of a method for manufacturing a transistor according to one or more exemplary embodiments of the present application.

FIG. 3 is a schematic diagram of relevant steps in the manufacturing process according to one or more exemplary embodiments of the present application.

FIG. 4 is a schematic diagram of relevant steps in the manufacturing process according to one or more exemplary embodiments of the present application.

FIG. 5 is a schematic diagram of relevant steps in the manufacturing process according to one or more exemplary embodiments of the present application.

FIG. 6 is a schematic diagram of relevant steps in the manufacturing process according to one or more exemplary embodiments of the present application.

FIG. 7 is a schematic diagram of relevant steps in the manufacturing process according to one or more exemplary embodiments of the present application.

FIG. 8 is a schematic diagram of relevant steps in the manufacturing process according to one or more exemplary embodiments of the present application.

FIG. 9 is a schematic diagram of relevant steps in the manufacturing process according to one or more exemplary embodiments of the present application.

FIG. 10 is a schematic diagram of relevant steps in a manufacturing process according to one or more exemplary embodiments of the present application.

FIG. 11 is a flowchart of a method for manufacturing a transistor according to one or more exemplary embodiments of the present application.

FIG. 12 is a schematic diagram of relevant steps in the manufacturing process according to one or more exemplary embodiments of the present application.

FIG. 13 is a schematic diagram of relevant steps in the manufacturing process according to one or more exemplary embodiments of the present application.

FIG. 14 is a schematic diagram of relevant steps in the manufacturing process according to one or more exemplary embodiments of the present application.

FIG. 15 is a schematic diagram of related steps in the manufacturing process according to one or more exemplary embodiments of the present application.

FIG. 16 is a schematic diagram of related steps in the manufacturing process according to one or more exemplary embodiments of the present application.

FIG. 17 is a schematic diagram of related steps in the manufacturing process according to one or more exemplary embodiments of the present application.

FIG. 18 is a schematic diagram of relevant steps in the manufacturing process according to one or more exemplary embodiments of the present application.

FIG. 19 is a schematic diagram of relevant steps in the manufacturing process according to one or more exemplary embodiments of the present application.

FIG. 20 is a schematic diagram of relevant steps in a manufacturing process according to one or more exemplary embodiments of the present application.

FIG. 21 is a perspective view of a vertical channel transistor according to one or more exemplary embodiments of the present application.

FIG. 22 is a schematic diagram of a stacked structure according to one or more exemplary embodiments of the present application.

FIG. 23 is a schematic diagram of a stacked structure according to one or more exemplary embodiments of the present application.

FIG. 24 is a schematic diagram of a formation process of a stacked structure according to one or more exemplary embodiments of the present application.

FIG. 25 is a schematic diagram of a formation process of a stacked structure according to another or more exemplary embodiments of the present application.

FIG. 26 is a schematic diagram of a formation process of a stacked structure according to another or more exemplary embodiments of the present application.

FIG. 27 is a schematic diagram of a formation process of a stacked structure according to another or more exemplary embodiments of the present application.

### DETAILED DESCRIPTION

In order to make the object, technical solution, and advantages of the present application clearer, embodiments of the present application will be described in further detail below with reference to the accompanying drawings.

In an embodiment of the present application, a method for manufacturing a transistor is provided, and optionally, the method for manufacturing a transistor is mainly applied to a process for manufacturing a vertical channel transistor. Especially for transistors where the channel is surrounded by the gate.

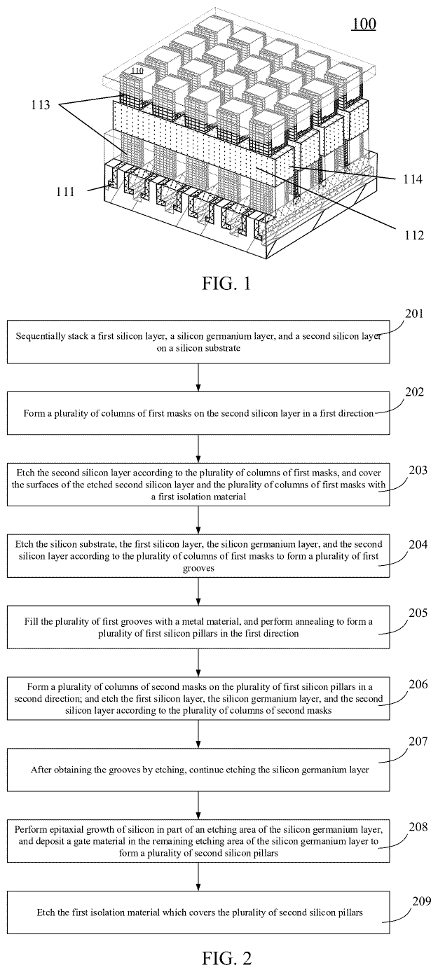

First, the structure of the vertical channel transistor will be introduced. As shown in FIG. 1, the transistor array 100 includes a plurality of transistor units 110. Each transistor unit 110 includes a Bit Line (BL) 111, a Word Line (WL) 112, a source/drain 113, and a gate 114.

Herein, a plurality of transistor units 110 in a same column in the transistor array 100 are coupled to an extended bit line 111 such that the plurality of transistor units 110 in the same column are in communication; a plurality of transistor units 110 in a same row in the transistor array 100 are coupled to an extended word line 112 such that the plurality of transistor units 110 in the same row are in communication.

Herein, the word line 112 is connected to the gate electrode 114 and turns on the transistor unit 110 as a gate line; the bit line 111 is connected to the source/drain 113 and serves as a data signal write line. The word line 112 is wrapped around the periphery of the gate 114.

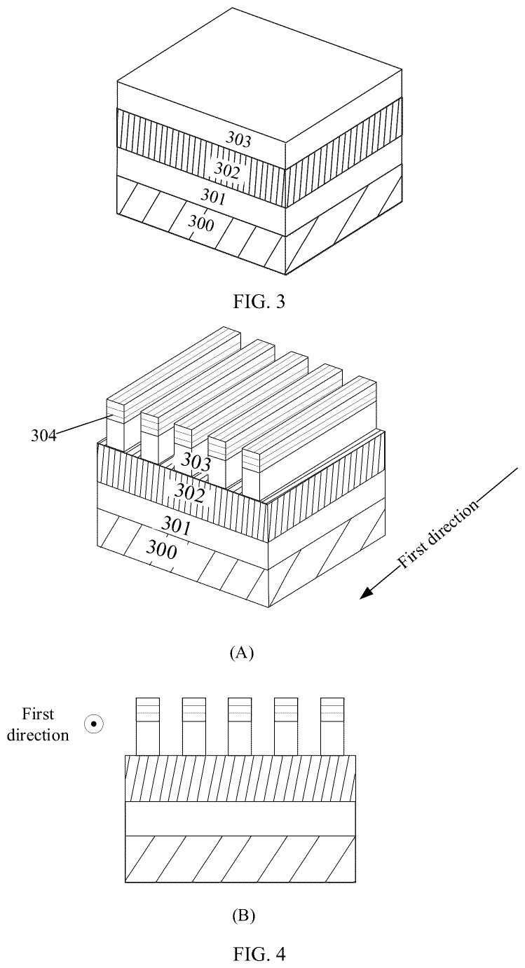

In conjunction with the above description of the transistor, FIG. 2 is a flowchart of a method for manufacturing a transistor according to an exemplary embodiment of the present application, and as shown in FIG. 2, the method includes the following steps.

Step 201: sequentially stacking a first silicon layer, a silicon germanium layer, and a second silicon layer on a silicon substrate;

In conjunction with reference to FIG. 3, FIG. 3 shows a first silicon layer 301, a silicon germanium layer 302, and a second silicon layer 303 obtained by sequentially being stacked on the silicon substrate 300. The first silicon layer 301 is in contact with the silicon substrate 300. Step 202: forming a plurality of columns of first masks on the second silicon layer in the first direction;

The plurality of columns of first masks are formed on the second silicon layer 303 in the first direction. The first direction is a bit line direction. Optionally, the mask material is also referred to as a photoresist material, a photoresist, or the like.

Step 203: etching the second silicon layer according to the plurality of columns of first masks, and covering the surfaces of the etched second silicon layer and the plurality of first masks with a first isolation material;

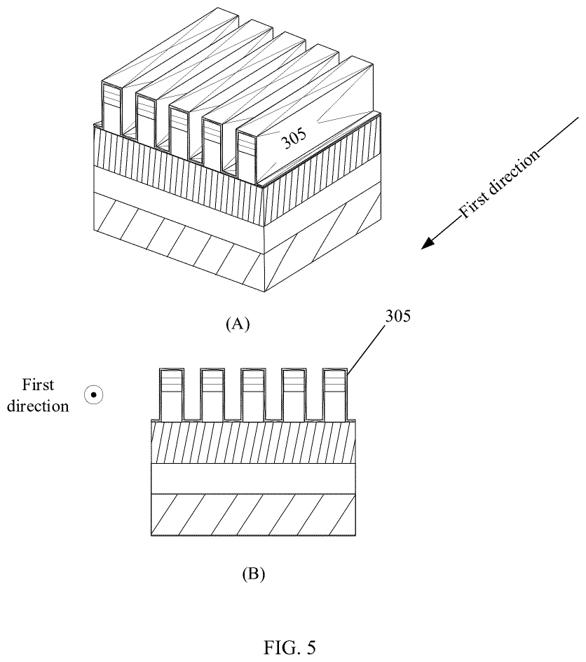

In conjunction with reference to FIG. 4, FIG. 4 shows a schematic diagram of a three-dimensional structure obtained by etching the second silicon layer 303 according to the plurality of columns of first masks 304. FIG. 4 shows that regions of the second silicon layer 303 that are not covered by the plurality of columns of first masks 304 are to be etched off. Part (A) of FIG. 4 shows a three-dimensional schematic view of the three-dimensional structure obtained after etching. Part (B) of FIG. 4 shows a two-dimensional plan view obtained by viewing the three-dimensional structure in the first direction. In one embodiment, the second silicon layer 303 is etched using a SADP (Self-Aligned Double Patterning) process.

In conjunction with reference to FIG. 5, FIG. 5 shows a schematic diagram of a three-dimensional structure obtained by covering the surfaces of the etched second silicon layer 303 and the plurality of first masks 304 with a first isolation material 305. Part (A) of FIG. 5 shows a three-dimensional schematic view of the three-dimensional structure. Part (B) of FIG. 5 shows a two-dimensional plan view obtained by viewing the three-dimensional structure in a first direction. In one embodiment, the first isolation material 305 is nitride. Optionally, the first isolation material 305 is silicon nitride.

In one embodiment, the surfaces of the etched second silicon layer 303 and the plurality of first masks 304 are covered with the first isolation material 305 by an ALD (Atomic Layer Deposition) process.

Step 204: etching the silicon substrate, the first silicon layer, the silicon germanium layer, and the second silicon layer according to the plurality of columns of first masks to form a plurality of first grooves;

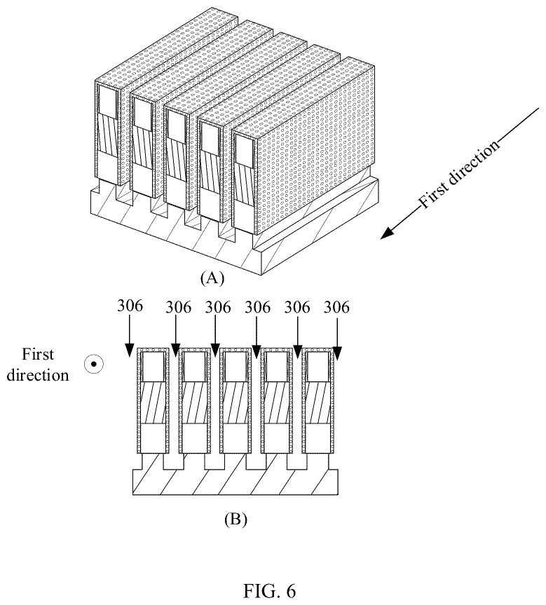

In conjunction with reference to FIG. 6, FIG. 6 shows a plurality of first grooves 306 formed after etching the silicon substrate 300, the first silicon layer 301, the silicon germanium layer 302, and the second silicon layer 303 according to the plurality of columns of first masks 304.

Step 205: filling and annealing a metal material in the plurality of first grooves to form a plurality of first silicon pillars in the first direction;

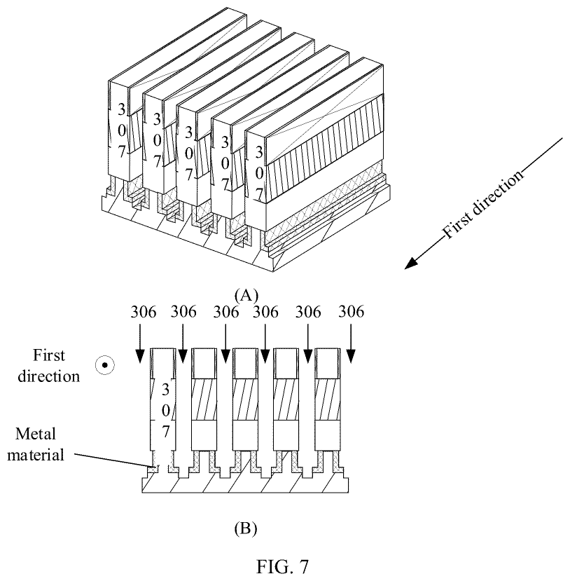

In conjunction with reference to FIG. 7, FIG. 7 shows a plurality of first silicon pillars 307 in the first direction. After the plurality of first grooves 306 are filled with the metal material and annealed, the metal material will diffuse to the silicon substrate portions included in the plurality of first silicon pillars 307. Part (A) of FIG. 7 shows a three-dimensional view of the three-dimensional structure of the plurality of first silicon pillars 307. Part (B) of FIG. 7 shows a two-dimensional plan view of the corresponding three-dimensional structure as viewed in the first direction.

Step 206: forming a plurality of columns of second masks on the plurality of first silicon pillars in a second direction; etching the first silicon layer, the silicon germanium layer and the second silicon layer according to the plurality of columns of second masks;

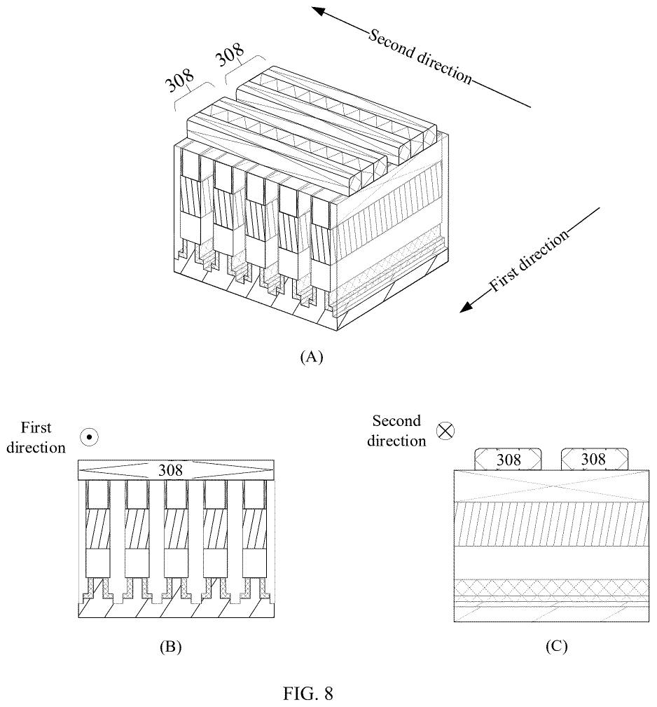

Optionally, the second direction is a word line direction. In conjunction with reference to FIG. 8, FIG. 8 shows a plurality of columns of second masks 308 deposited on the plurality of first silicon pillars 307 in the second direction. Part (A) of FIG. 8 shows a three-dimensional view of a three-dimensional structure obtained by depositing the plurality of columns of second masks 308. Part (B) of FIG. 8 shows a two-dimensional plan view of the corresponding three-dimensional structure as viewed in the first direction. Part (C) of FIG. 8 shows a two-dimensional plan view of the corresponding three-dimensional structure as viewed in the second direction.

Step 207: continuing etching the silicon germanium layer on the basis of the grooves obtained by etching;

In one embodiment, based on the etching operation performed in step 206, etched grooves will be obtained, and the silicon germanium layer 302 will continue to be etched on the basis of the grooves.

In step 208, performing silicon epitaxy in part of an etched region of the silicon germanium layer, depositing a gate material in a remaining etched region of the silicon germanium layer to form a plurality of second silicon pillars;

In one embodiment, silicon is epitaxially grown in regions where part of the silicon germanium layer 302 has been etched, and gate material is deposited in the remaining unetched regions to form a plurality of second silicon pillars. The plurality of second silicon pillars are distributed in an array in the first direction and the second direction. Optionally, the gate material includes a gate oxide layer material, a high K material, and a gate metal layer material. Optionally, the gate material is deposited within the voids of the upper middle portions of the plurality of second silicon pillars by an ALD process.

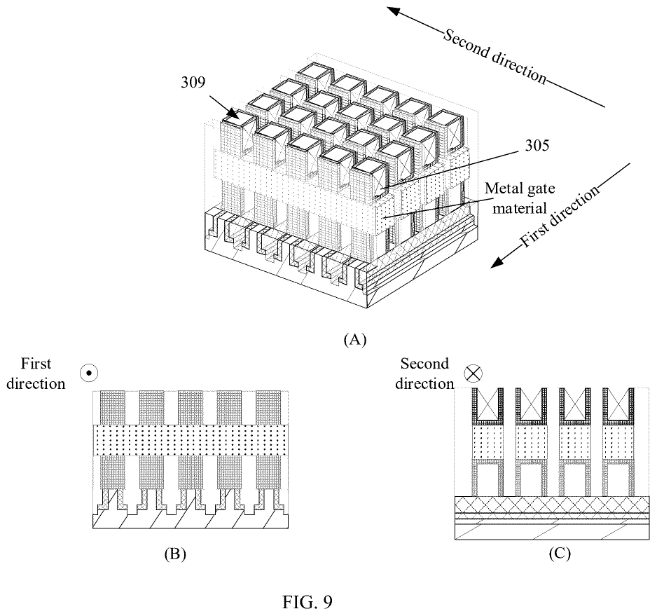

In conjunction with reference to FIG. 9, FIG. 9 shows a plurality of second silicon pillars 309 resulting from operations of epitaxial growth of silicon and depositing metal gate material. Part (A) of FIG. 9 shows a perspective view of the plurality of second silicon pillars 309. Part (B) of FIG. 9 shows a two-dimensional view of the corresponding three-dimensional structure as viewed in the first direction. Part (C) of FIG. 9 shows a two-dimensional view of the corresponding three-dimensional structure as viewed in the second direction.

Step 209: etching the first isolation material covered by the plurality of second silicon pillars.

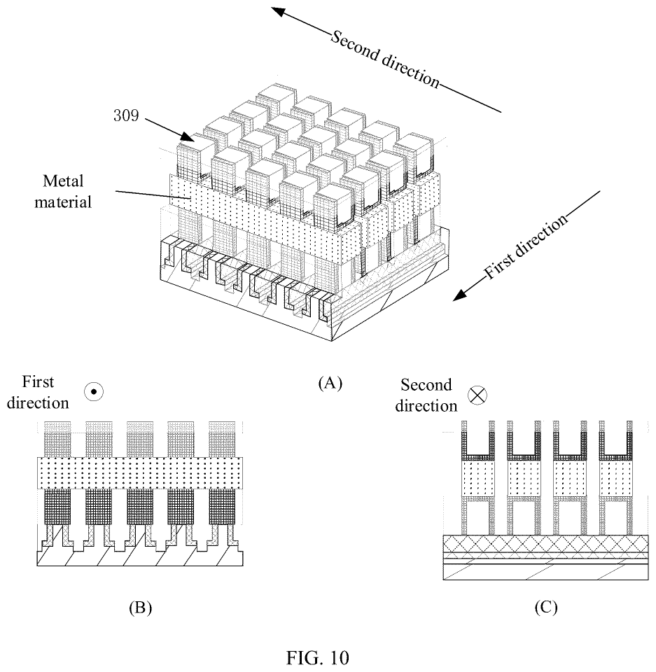

In conjunction with reference to FIG. 10, FIG. 10 shows a plurality of second silicon pillars 309 after performing etching of the first isolation material 305. Part (A) of FIG. 10 shows a perspective view of the plurality of second silicon pillars 309 after etching the first isolation material. Part (B) of FIG. 10 shows a two-dimensional view of the plurality of second silicon pillars 309 as viewed in the first direction. Part (C) of FIG. 10 shows a two-dimensional view of the plurality of second silicon pillars 309 as viewed in the second direction. Comparing FIGS. 9 and 10, it can be found that the first isolation material 305 has been removed.

In summary, by covering the surface of the second silicon layer 303 etched according to the first mask 304 with the first isolation material 305, the second silicon layer 303 is protected, and the metal contamination of the second silicon layer 303 that may be generated in the subsequent metal deposition process is avoided, thereby avoiding short circuit between the source/drain and the gate.

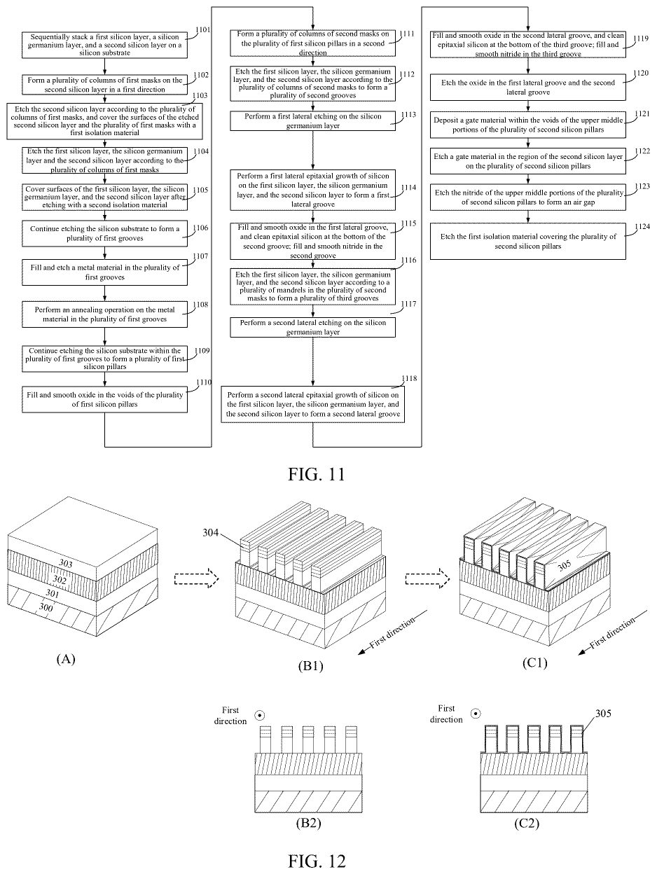

FIG. 11 shows a flowchart of a method for manufacturing a transistor according to an exemplary embodiment of the present application, the method including following steps.

Step 1101: sequentially stacking a first silicon layer, a silicon germanium layer, and a second silicon layer on a silicon substrate;

In conjunction with reference to FIG. 12, part (A) of FIG. 12 shows a three-dimensional structure in which a first silicon layer 301, a silicon germanium layer 302, and a second silicon layer 303 are sequentially stacked on a silicon substrate 300. The first silicon layer 301 is in contact with the silicon substrate 300.

Step 1102: forming a plurality of columns of first masks on the second silicon layer in a first direction;

In conjunction with reference to FIG. 12, part (B1) of FIG. 12 shows a plurality of columns of first masks 304 deposited on the second silicon layer 303 in the first direction. Optionally, the first direction is a bit line direction. Part (B2) of FIG. 12 shows a two-dimensional plan view of the corresponding three-dimensional structure as viewed in the first direction.

Step 1103: etching the second silicon layer according to the plurality of columns of first masks, and covering the surfaces of the etched second silicon layer and the plurality of first masks with a first isolation material;

Part (B1) of FIG. 12 also shows a three-dimensional view of a three-dimensional structure obtained by performing an etching operation on the second silicon layer 303 according to the plurality of columns of first masks 304. Part (B2) of FIG. 12 also shows a two-dimensional view of a three-dimensional structure obtained by performing an etching operation on the second silicon layer 303 as viewed in the first direction.

The part (C1) of FIG. 12 shows that the surface of the etched second silicon layer 303 and the plurality of first masks 304 is covered with a first isolation material 305. In one embodiment, the first isolation material 305 is a nitride. Optionally, the first isolation material 305 is silicon nitride. Part (C2) of FIG. 12 also shows a two-dimensional view of the corresponding three-dimensional structure as viewed in the first direction.

In one embodiment, the surfaces of the etched second silicon layer 303 and the plurality of first masks 304 are covered with the first isolation material 305 by an ALD (Atomic Layer Deposition) process.

Step 1104: etching the first silicon layer, the silicon germanium layer and the second silicon layer according to the plurality of columns of first masks;

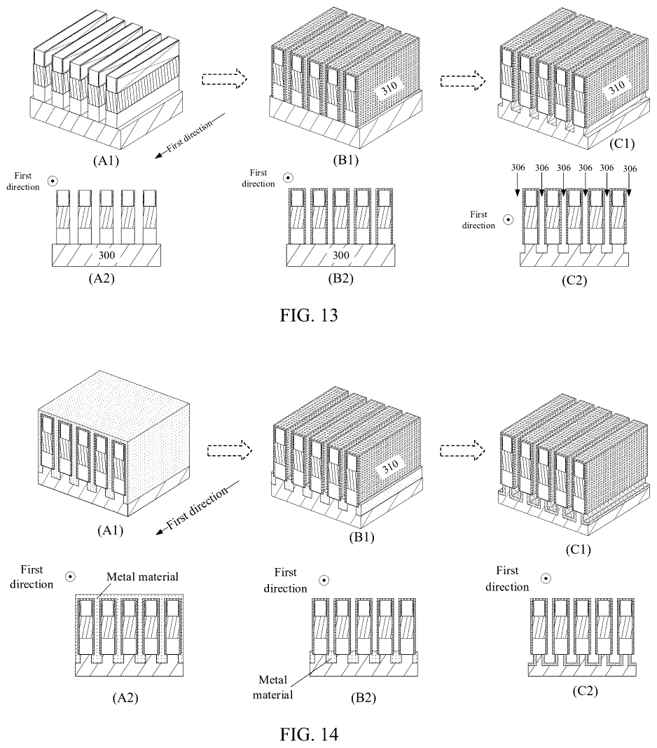

Part (A1) of FIG. 13 shows a schematic perspective view after the first silicon layer 301, the silicon germanium layer 302, and the second silicon layer 303 are etched according to the plurality of columns of first masks 304. Part (A2) of FIG. 13 shows a two-dimensional plan view after the first silicon layer 301, the silicon germanium layer 302, and the second silicon layer 303 are etched as viewed in the first direction.

It can be understood that after the etching operation of step 1104 is performed, a pattern of the bit line in the transistor can be observed in the first direction.

Step 1105: covering surfaces of the first silicon layer, the silicon germanium layer, and the second silicon layer after etching with a second isolation material;

In conjunction with reference to FIG. 13, part (B1) of FIG. 13 shows a schematic perspective view in which the surfaces of the first silicon layer 301, the silicon germanium layer 302, and the second silicon layer 303 after etching are covered with the second isolation material 310. In one embodiment, the second isolation material is nitride. Optionally, the second isolation material is silicon nitride. Part (B2) of FIG. 13 shows a two-dimensional plan view of the corresponding three-dimensional structure as viewed in the first direction.

In one embodiment, the surfaces of the first silicon layer 301, the silicon germanium layer 302, and the second silicon layer 303 after etching are covered with a second isolation material 310 by an ALD (Atomic Layer Deposition) process.

Step 1106: continuing etching the silicon substrate to form a plurality of first grooves;

In conjunction with reference to FIG. 13, part (C1) of FIG. 13 shows a plurality of first grooves 306. In one embodiment, etching of the silicon substrate 300 continues in the vertical direction of the first silicon layer 301, the silicon germanium layer 302, and the second silicon layer 303, and then a transverse etching is performed to form a plurality of first grooves 306. The part (C2) of FIG. 13 shows the plurality of first grooves 306 as viewed in the first direction.

In one embodiment, the silicon substrate 300 is continued to be etched within the plurality of first grooves 306 by a wet process to form the plurality of first grooves 306.

Step 1107: filling and etching a metal material in the plurality of first grooves;

In conjunction with reference to FIGS. 13 and 14, part (A1) of FIG. 14 shows a perspective view of the plurality of first grooves 306 filled with a metal material. Part (A2) of FIG. 14 shows a two-dimensional plan view of the corresponding three-dimensional structure as viewed in the first direction. In one embodiment, the metal material is tungsten.

In conjunction with reference to FIG. 14, part (B1) of FIG. 14 shows a three-dimensional structure after the metal material within the plurality of first grooves 306 has been etched. The part (B2) of FIG. 14 shows a two-dimensional plan view after the metal material within the plurality of first grooves 306 is etched as viewed in the first direction. It can be found that the upper surface of the etched metal material is higher than the lower surface of the second isolation material 310. The second isolation material 310 protects the first silicon layer 301, the silicon germanium layer 302, and the second silicon layer 303 from being contaminated by the filled metal and avoids short circuit.

Step 1108: performing an annealing operation on the metal material in the plurality of first grooves;

In conjunction with reference to FIG. 14, part (C1) of FIG. 14 shows the three-dimensional structure after an annealing operation is performed on the metal material within the plurality of first grooves 306. The part (C2) of FIG. 14 shows a two-dimensional plan view of the corresponding three-dimensional structure as viewed in the first direction. The purpose of the annealing operation is to diffuse the metal material to the silicon substrate at the bottom of the first silicon pillar to cover the bottom of the first silicon pillar with silicide, which is used to form the bit line of the metal gate transistor.

Step 1109, continuing etching the silicon substrate within the plurality of first grooves to form a plurality of first silicon pillars;

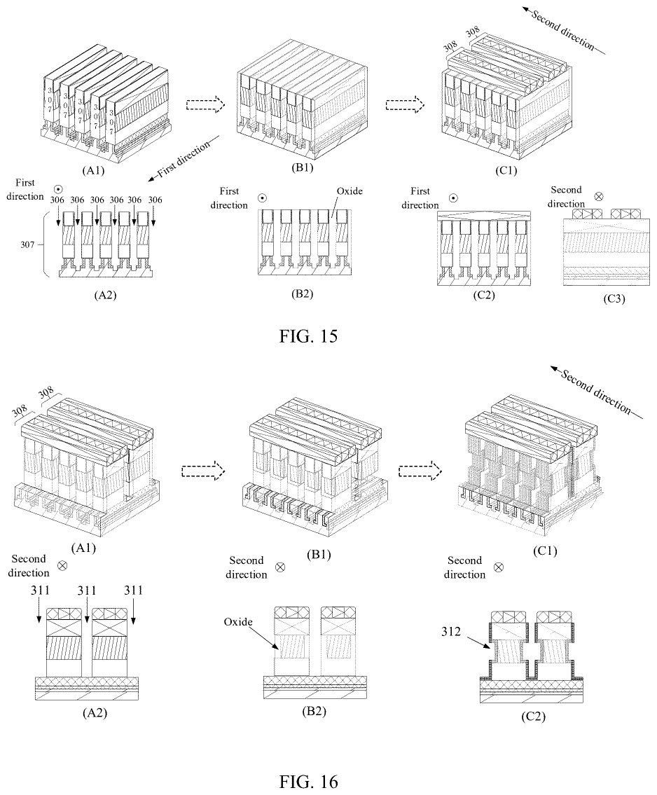

In conjunction with reference to FIG. 15, part (A1) of FIG. 15 shows a three-dimensional structure of a plurality of first silicon pillars 307. Part (A2) of FIG. 15 shows a two-dimensional plan view of the plurality of first silicon pillars 307 as viewed in the first direction. In one embodiment, the silicon substrate will continue to be etched in the plurality of first grooves 306 to separate the plurality of first silicon pillars 307, avoid the presence of connected silicide between two first silicon pillars 307, and thus avoid short-circuiting of bit lines between the plurality of first silicon pillars 307.

Step 1110: filling and smoothing oxide in the voids of the plurality of first silicon pillars; In conjunction with reference to FIG. 15, part (B1) of FIG. 15 shows the three-dimensional structure after oxide is filled within the voids of the plurality of first silicon pillars and smoothed. Part (B2) of FIG. 15 shows a two-dimensional plan view of the three-dimensional structure after the oxide is filled and smoothed as viewed in the first direction. In one embodiment, the smoothing operation is performed by CMP (Chemical Mechanical Polishing). In one embodiment, the oxide is silicon dioxide.

Step 1111: forming a plurality of columns of second masks on the plurality of first silicon pillars in a second direction;

Optionally, the second direction is a word line direction. In conjunction with reference to FIG. 15, part (C1) of FIG. 15 shows a three-dimensional structure resulting from depositing a plurality of columns of second masks 308 on the plurality of first silicon pillars 307. Part (C2) of FIG. 15 shows a two-dimensional plan view of the three-dimensional structure after the plurality of columns of second masks 308 are deposited as viewed in the first direction. Part (C3) of FIG. 15 shows a two-dimensional plan view of the three-dimensional structure after the plurality of columns of second masks 308 are deposited as viewed in the second direction. In one embodiment, the second mask 308 is a three-layer structure consisting of a side wall, a mandrel, and a side wall.

Step 1112: etching the first silicon layer, the silicon germanium layer, and the second silicon layer according to the plurality of columns of second masks to form a plurality of second grooves;

In one embodiment, regions of the first silicon layer 301, the silicon germanium layer 302, and the second silicon layer 303 that are not covered by the plurality of columns of second masks 308 will be removed by etching. In conjunction with reference to FIG. 16, part (A1) of FIG. 16 shows a three-dimensional structure of a plurality of second grooves 311 formed by etching the first silicon layer 301, the silicon germanium layer 302, and the second silicon layer 303 according to the plurality of columns of second masks 308. Part (A2) of FIG. 16 shows a corresponding two-dimensional plan view as viewed in the second direction.

In one embodiment, the first silicon layer 301, the silicon germanium layer 302, and the second silicon layer 303 are etched according to the plurality of columns of second masks 308 by a dry process.

Step 1113: performing a first lateral etching on the silicon germanium layer;

A first lateral etching is performed on the silicon germanium layer 302. In one embodiment, lateral etching is performed on both sides of the silicon germanium layer 302. The corresponding etching depth of each side is approximately ½ the thickness of the side wall. In one embodiment, the lateral etching is performed by an ALE (Atomic Layer Etch) process.

Part (B1) of FIG. 16 shows a perspective schematic view of a three-dimensional structure obtained by the first lateral etching. Part (B2) of FIG. 16 shows a two-dimensional schematic view of the three-dimensional structure obtained by the first lateral etching.

Step 1114: performing a first lateral epitaxial growth of silicon on the first silicon layer, the silicon germanium layer, and the second silicon layer to form a first lateral groove;

Part (C1) of FIG. 16 shows a perspective view of a first lateral groove 312 formed by performing a first lateral epitaxial growth of silicon on the first silicon layer 301, the silicon germanium layer 302, and the second silicon layer 303. Part (C2) of FIG. 16 shows a two-dimensional plan view of the first lateral groove 312 formed by performing the first lateral silicon epitaxy on the first silicon layer 301, the silicon germanium layer 302, and the second silicon layer 303.

Step 1115: filling and smoothing oxide in the first lateral groove, and cleaning epitaxial silicon at the bottom of the second groove; filling and smoothing nitride in the second groove;

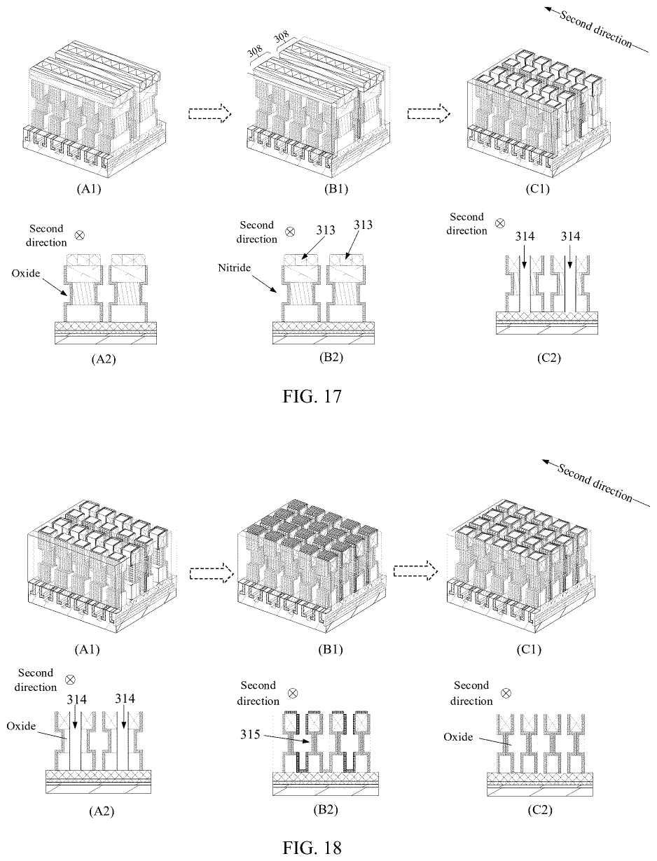

In conjunction with reference to FIG. 17, part (A1) of FIG. 17 shows a three-dimensional schematic view of the three-dimensional structure after the oxide is filled in the first lateral groove 312 and smoothed, and the epitaxial silicon at the bottom of the second groove 311 is cleaned. Part (A2) of FIG. 17 shows a two-dimensional plan view of the corresponding three-dimensional structure as viewed in the second direction.

Part (B1) of FIG. 17 shows a three-dimensional schematic view of the three-dimensional structure after nitride is filled in the second groove 311 and smoothed. Part (B2) of FIG. 17 shows a two-dimensional schematic view of the three-dimensional structure after nitride is filled in the second groove 311 and smoothed. In one embodiment, the second mask 308 is a three-layer structure consisting of a side wall, a mandrel 313, and a side wall.

In one embodiment, the first lateral groove 312 is filled with oxide by an ALD process.

In one embodiment, the oxide is silicon dioxide. In one embodiment, the nitride is silicon nitride.

Step 1116: etching the first silicon layer, the silicon germanium layer, and the second silicon layer according to a plurality of mandrels in the plurality of second masks to form a plurality of third grooves;

Part (C1) of FIG. 17 shows a three-dimensional structure obtained by etching the first silicon layer 301, the silicon germanium layer 302, and the second silicon layer 303 according to the plurality of mandrels 313 in the plurality of second masks 308. Part (C2) of FIG. 17 shows a two-dimensional schematic view of the corresponding three-dimensional structure as viewed in the second direction. Part (C2) of FIG. 17 shows that regions covered by the mandrels 313 have been etched. Part (C2) of FIG. 17 shows the third groove 314 obtained by etching.

Step 1117: performing a second lateral etching on the silicon germanium layer;

A second lateral etching is performed on the silicon germanium layer 302. In one embodiment, the purpose of the second lateral etching is to etch and clean the silicon germanium material of the silicon germanium layer 302 in conjunction with the first lateral etch.

In conjunction with reference to FIG. 18, part (A1) of FIG. 18 shows a three-dimensional schematic view of the three-dimensional structure obtained by the second lateral etching. Part (A2) of FIG. 18 shows a two-dimensional schematic view of the three-dimensional structure obtained as viewed in the second direction.

Step 1118: performing a second lateral silicon epitaxy on the first silicon layer, the silicon germanium layer, and the second silicon layer to form a second lateral groove;

Part (B1) of FIG. 18 shows a second lateral groove 315 formed by performing a second lateral epitaxial growth of silicon on the first silicon layer 301, the silicon germanium layer 302, and the second silicon layer 303. Part (B2) of FIG. 18 shows a two-dimensional plan view of the corresponding three-dimensional structure as viewed in the second direction.

Step 1119: filling and smoothing oxide in the second lateral groove, and cleaning epitaxial silicon at the bottom of the third groove; filling and smoothing nitride in the third groove;

Part (C1) of FIG. 18 shows a three-dimensional schematic diagram of a three-dimensional structure obtained by filling and smoothing oxide in the second lateral groove 315, and removing the silicon obtained by epitaxial growth at the bottom of the third groove 314. Part (C2) of FIG. 18 shows a two-dimensional schematic view of the corresponding three-dimensional structure as viewed in the second direction.

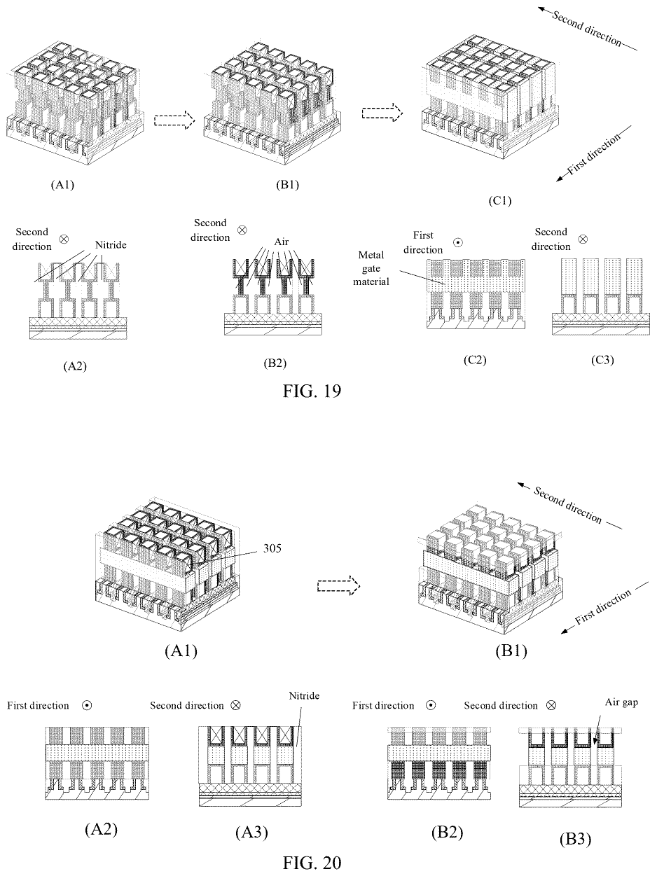

In conjunction with reference to FIG. 19, part (A1) of FIG. 19 shows a three-dimensional schematic diagram of a three-dimensional structure obtained by filling and smoothing nitride in the third groove 314. Part (A2) of FIG. 19 shows a two-dimensional plan view of the corresponding three-dimensional structure as viewed in the second direction.

In one embodiment, the second lateral groove 315 is filled with oxide by an ALD process. In one embodiment, the oxide is silicon dioxide. In one embodiment, the nitride is silicon nitride.

Step 1120: etching the oxide in the first lateral groove and the second lateral groove;

In conjunction with reference to FIG. 19, parts (B1) and (B2) of FIG. 19 show that oxide filled in the first lateral groove 312 and the second lateral groove, 315 is etched, and at this time, both the first lateral groove 312 and the second lateral groove 315 are filled with air. Part (B1) of FIG. 19 is a three-dimensional schematic view. Part (B2) of FIG. 19 is a two-dimensional schematic view of the corresponding three-dimensional structure as viewed in the second direction.

Step 1121: depositing a gate material within the voids of the upper middle portions of the plurality of second silicon pillars;

Herein, an upper middle portion includes a gate layer and a second silicon layer. In conjunction with reference to FIG. 19, part (C1) of FIG. 19 shows a three-dimensional schematic view of a three-dimensional structure in which gate material is deposited within voids of upper middle portions of the plurality of second silicon pillars 309. Part (C2) of FIG. 19 shows a two-dimensional plan view of the corresponding three-dimensional structure as viewed in the first direction. Part (C3) of FIG. 19 shows a two-dimensional plan view of the corresponding three-dimensional structure as viewed in the second direction. Optionally, the gate material includes a gate oxide layer material, a high K material, and a gate metal layer material. Optionally, the gate material is deposited within the voids of the upper middle portions of the plurality of second silicon pillars by an ALD process.

Step 1122: etching a gate material in the region of the second silicon layer on the plurality of second silicon pillars;

In conjunction with reference to FIGS. 19 and 20, part (A1) of FIG. 20 shows a three-dimensional schematic view of a three-dimensional structure after the gate material of the region of the second silicon layer 303 on the plurality of second silicon pillars 309 is etched. Part (A2) of FIG. 20 shows a two-dimensional schematic view of the corresponding three-dimensional structure as viewed in the first direction. Part (A3) of FIG. 20 shows a two-dimensional schematic view of the corresponding three-dimensional structure as viewed in the second direction.

Step 1123: etching the nitride of the upper middle portions of the plurality of second silicon pillars to form an air gap;

Part (B1) of FIG. 20 shows a three-dimensional schematic view of a three-dimensional structure formed after the nitride of the upper middle portions of the plurality of second silicon pillars is etched. Part (B2) of FIG. 20 shows a two-dimensional schematic view of the corresponding three-dimensional structure as viewed in the first direction. Part (B3) of FIG. 20 shows a two-dimensional schematic view of the corresponding three-dimensional structure as viewed in the second direction.

In one embodiment, the nitride of upper middle portions of the plurality of second silicon pillars is etched, and the nitride is deposited at a top position of the plurality of second silicon pillars to form an air gap. It will be appreciated that the deposition of nitride at the top position acts as a seal, allowing the air gap after etching to stabilize. Part (B1) of FIG. 20 shows that nitride is deposited at the top positions of the plurality of second silicon pillars.

Step 1124: etching the first isolation material covered by the plurality of second silicon pillars.

Part (B1) of FIG. 20 also shows a three-dimensional schematic view of a three-dimensional structure formed after the first isolation material 305 covering the plurality of second silicon pillars 309 is etched. Part (B2) of FIG. 20 shows a two-dimensional schematic view of the corresponding three-dimensional structure as viewed in the first direction. Part (B3) of FIG. 20 shows a two-dimensional schematic view of the corresponding three-dimensional structure as viewed in the second direction.

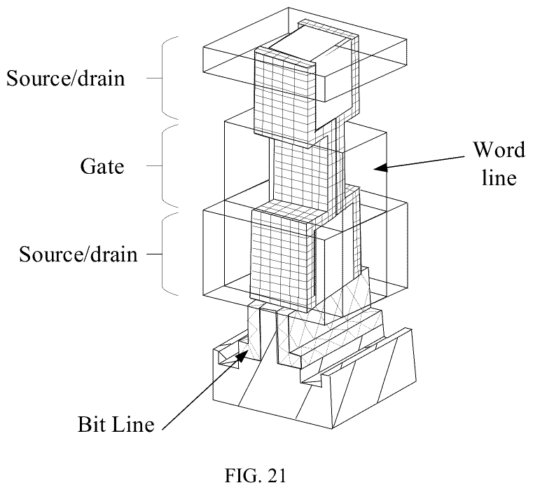

In conjunction with reference to FIG. 21, FIG. 21 shows the resulting vertical ring gate transistor.

Based on the method embodiments shown in FIGS. 2 and 11, well isolation is also formed in the stacked structure when steps 201 and 1101 are performed.

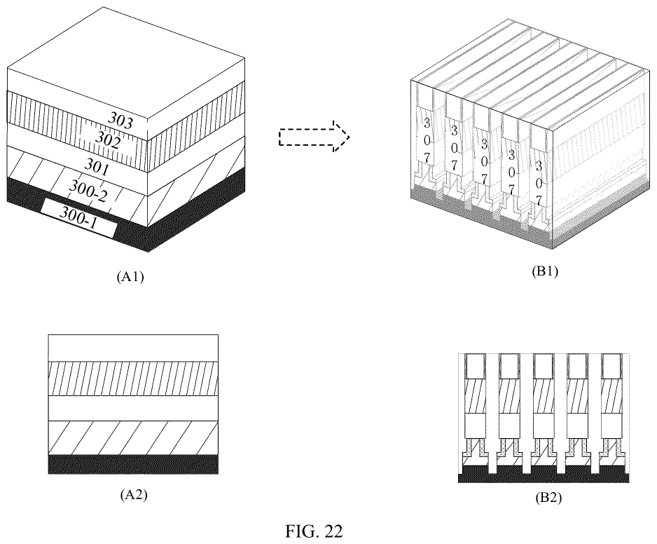

In one embodiment, in conjunction with reference to FIG. 22, part (A1) of FIG. 22 shows the stacked structure after the well isolation is formed. Part (A2) of FIG. 22 shows a two-dimensional plan view of the stacked structure. The stacked structure after considering well isolation includes a silicon substrate 300, a first silicon layer 301, a silicon germanium layer 302, and a second silicon layer 303. Further, the silicon substrate 300 includes an upper portion silicon substrate 300-1 and a lower portion silicon substrate 300-2. Alternatively, the lower portion silicon substrate 300-2 is doped as N-type, the upper portion silicon substrate 300-1 is doped as P-type, and the first silicon layer 301 is doped as P-type. Optionally, the lower portion silicon substrate 300-2 is doped as P-type, the upper portion silicon substrate 300-1 is doped as N-type, and the first silicon layer 301 is doped as N-type.

It can be noted that part (B1) of FIG. 22 shows the three-dimensional structure of the plurality of first silicon pillars 307 obtained after considering well isolation. Part (B2) of FIG. 22 shows a plan view corresponding to the three-dimensional structure. At this time, the etching depth at which the longitudinal etching of the first silicon pillars 307 is performed reaches only the upper portion silicon substrate 300-1, and the plurality of first silicon pillars 307 (i.e., bit lines) are isolated from each other by PN junction structures to prevent leakage between the first silicon pillars 307.

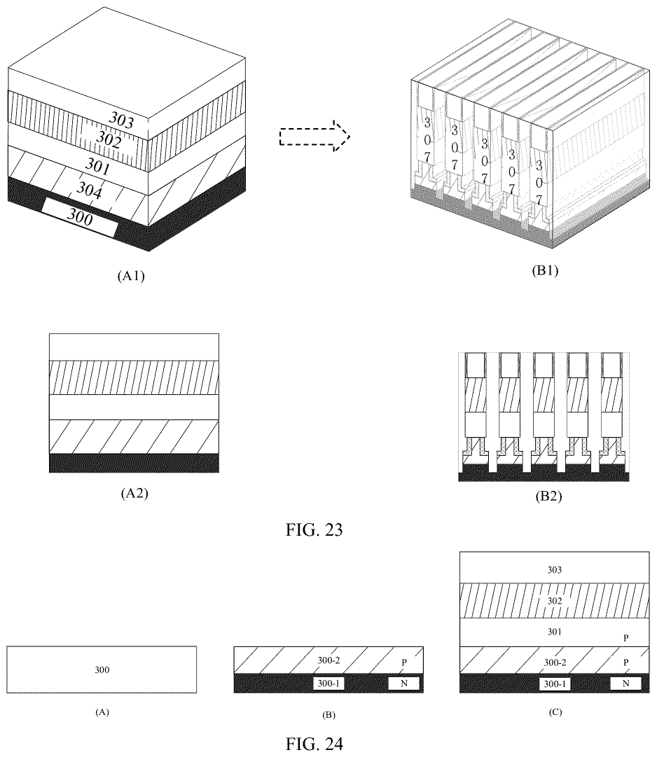

In one embodiment, in conjunction with reference to FIG. 23, part (A1) of FIG. 23 shows the stacked structure after the well isolation is formed. Part (A2) of FIG. 23 shows a two-dimensional plan view of the stacked structure. The stacked structure after considering well isolation includes a silicon substrate 300, a first silicon layer 301, a silicon germanium layer 302, a second silicon layer 303, and a third silicon layer 304 located between the silicon substrate 300 and the first silicon layer. Optionally, the silicon substrate 300 is doped as P-type, and the first silicon layer 301 and the third silicon layer 304 are doped as N-type.

It can be noted that part (B1) of FIG. 23 shows the three-dimensional structure of the plurality of first silicon pillars 307 obtained after considering well isolation. Part (B2) of FIG. 23 shows a plan view corresponding to the three-dimensional structure. At this time, the etching depth at which the longitudinal etching of the first silicon pillars 307 is performed only reaches the third silicon layer 304, and the plurality of first silicon pillars 307 (i.e., bit lines) are isolated from each other by PN junction structures to prevent leakage between the first silicon pillars 307.

Schematically, the following four possible implementations of step 201 and step 1101 are provided.

A first possible implementation: obtaining a silicon substrate; doping a lower portion silicon substrate in the silicon substrate as N-type, and doping an upper portion silicon substrate in the silicon substrate as P-type; stacking a first silicon layer, a silicon germanium layer, and a second silicon layer sequentially on the silicon substrate; doping the first silicon layer as P-type. Optionally, the silicon substrate lattice is restored by an annealing operation after doping the silicon substrate.

In conjunction with reference to FIG. 24, part (A) of FIG. 24 shows a silicon substrate 300; part (B) of FIG. 24 shows a lower portion silicon substrate 300-1 doped as N-type and an upper portion silicon substrate 300-2 doped as P-type. Part (C) of FIG. 24 shows a first silicon layer 301, a silicon germanium layer 302, and a second silicon layer 303 which are obtained by stacking, and the first silicon layer 301 is doped as P-type.

A second possible implementation: obtaining a silicon substrate; doping a lower portion silicon substrate in the silicon substrate as P-type and doping an upper portion silicon substrate in the silicon substrate as N-type; stacking a first silicon layer, a silicon germanium layer, and a second silicon layer sequentially on the silicon substrate; and doping the first silicon layer as N-type. Optionally, the silicon substrate lattice is restored by an annealing operation after doping the silicon substrate.

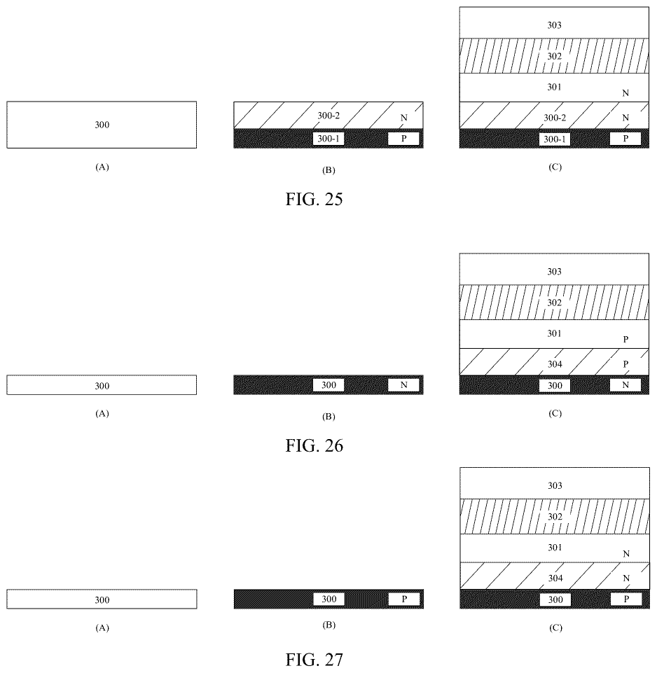

In conjunction with reference to FIG. 25, part (A) of FIG. 25 shows a silicon substrate 300; part (B) of FIG. 25 shows a lower portion silicon substrate 300-1 doped as P-type and an upper portion silicon substrate 300-2 doped as N-type. Part (C) of FIG. 25 shows a first silicon layer 301, a silicon germanium layer 302, and a second silicon layer 303 obtained by stacking, and the first silicon layer 301 is doped as N-type.

A third possible implementation: obtaining a silicon substrate; doping the silicon substrate as N-type; stacking a third silicon layer, a first silicon layer, a silicon germanium layer, and a second silicon layer sequentially on the silicon substrate; and doping the third silicon layer and the first silicon layer as P-type.

In conjunction with reference to FIG. 26, part (A) of FIG. 26 shows a silicon substrate 300; part (B) of FIG. 26 shows the silicon substrate 300 doped as N-type. Part (C) of FIG. 26 shows a third silicon layer 304, a first silicon layer 301, a silicon germanium layer 302, and a second silicon layer 303 obtained by stacking, the third silicon layer 304 is doped as P-type, and the first silicon layer 301 is doped as P-type.

A fourth possible implementation: obtaining a silicon substrate; doping the silicon substrate as P-type; stacking a third silicon layer, a first silicon layer, a silicon germanium layer, and a second silicon layer sequentially on the silicon substrate; and doping the third silicon layer and the first silicon layer as N-type.

In conjunction with reference to FIG. 27, part (A) of FIG. 27 shows a silicon substrate 300; part (B) of FIG. 26 shows the silicon substrate 300 doped as P-type. Part (C) of FIG. 27 shows a third silicon layer 304, a first silicon layer 301, a silicon germanium layer 302, and a second silicon layer 303 obtained by stacking, the third silicon layer 304 is doped as N-type, and the first silicon layer 301 is doped as N-type.

An embodiment of the present application provides an electronic device including a logic apparatus, wherein the logic apparatus includes a transistor as provided in the above embodiments. The logic apparatus can be applied to a logic operator, a memory, and the like.

Optionally, the electronic device includes a smartphone, a computer, a tablet, an artificial intelligence device, a wearable device, or a smart mobile terminal.

In the present application, the terms “first” and “second” are used for descriptive purposes only and cannot be interpreted as indicating or implying relative importance. The term “at least one” refers to one or more, and the term “plurality” refers to two or more, unless explicitly defined otherwise.

In the present application, the term “and/or” is only an association relationship describing association objects, and means that there may be three relationships, for example, A and/or B can mean that there are three situations: A alone, A and B at the same time, and B alone. In addition, the character “/” herein generally indicates that the related objects before and after are in an “or” relationship.

The above description is only an exemplary embodiment of the present application, and is not intended to limit the present application. Any modification, equivalent substitution, improvement, and the like made within the spirit and the principle of the present application should be included within the scope of protection of the present application.

1. A method for manufacturing a transistor, comprising:
stacking a first silicon layer, a silicon germanium layer, and a second silicon layer sequentially on a silicon substrate, wherein the first silicon layer is in contact with the silicon substrate; forming a plurality of columns of first masks on the second silicon layer in a first direction; etching the second silicon layer according to the plurality of columns of first masks, and covering surfaces of an etched second silicon layer and the plurality of columns of first masks with a first isolation material;
etching the silicon substrate, the first silicon layer the silicon germanium layer and the second silicon layer according to the plurality of columns of first masks to form a plurality of first grooves filling and annealing a metal material in the plurality of first grooves to form a plurality of first silicon pillars in the first direction;
forming a plurality of columns of second masks on the plurality of first silicon pillars in a second direction; etching the first silicon layer, the silicon germanium layer and the second silicon layer according to the plurality of columns of second masks; continuing etching the silicon germanium layer on a basis of grooves obtained by etching; performing silicon epitaxy in part of an etched region of the silicon germanium layer, depositing a gate material in a remaining etched region of the silicon germanium layer to form a plurality of second silicon pillars, wherein the plurality of second silicon pillars are distributed in an array in the first direction and the second direction;
etching the first isolation material covered by the plurality of second silicon pillars.

2. The method according to claim 1, wherein the filling and annealing a metal material in the plurality of first grooves to form a plurality of first silicon pillars in the first direction comprises:
filling and annealing a metal material in the plurality of first grooves;
continuing etching the silicon substrate within the plurality of first grooves to form the plurality of first silicon pillars.

3. The method according to claim 2, wherein the etching the silicon substrate, the first silicon layer, the silicon germanium layer, and the second silicon layer according to the plurality of columns of first masks to form a plurality of first grooves comprises:
etching the first silicon layer, the silicon germanium layer, and the second silicon layer according to the plurality of columns of first masks; covering surfaces of the first silicon layer, the silicon germanium layer, and the second silicon layer after etching with a second isolation material;
continuing etching the silicon substrate to form the plurality of first grooves.

4. The method according to claim 3, wherein the filling and annealing a metal material in the plurality of first grooves comprises:
filling and etching the metal material in the plurality of first grooves, an upper surface of the metal material after etching is higher than a lower surface of the second isolation material; and
performing an annealing operation on the metal material within the plurality of first grooves.

5. The method according to claim 1, wherein the etching the first silicon layer, the silicon germanium layer, and the second silicon layer according to the plurality of columns of second masks; continuing etching the silicon germanium layer on a basis of grooves obtained by etching; performing epitaxial growth of silicon in part of an etched region of the silicon germanium layer, depositing a gate material in a remaining etched region of the silicon germanium layer to form a plurality of second silicon pillars comprises:
etching the first silicon layer, the silicon germanium layer and the second silicon layer according to the plurality of columns of second masks to form a plurality of second grooves; performing a first lateral etching on the silicon germanium layer and then performing a first lateral silicon epitaxy on the first silicon layer, the silicon germanium layer, and the second silicon layer to form a first lateral groove;
etching the first silicon layer, the silicon germanium layer, and the second silicon layer according to a plurality of mandrels in the plurality of second masks to form a plurality of third grooves; performing a second lateral etching on the silicon germanium layer, and then performing a second lateral silicon epitaxy on the first silicon layer, the silicon germanium layer, and the second silicon layer to form a second lateral groove, wherein two lateral etchings completely remove a silicon germanium material of the silicon germanium layer; and
depositing a gate material within the first lateral groove and the second lateral groove to form the plurality of second silicon pillars.

6. The method according to claim 5,
after forming the first lateral groove, further comprising: filling and smoothing oxide in the first lateral groove, and clearing epitaxial silicon at a bottom of the second groove; filling and smoothing nitride in the second groove;
after forming the second lateral groove, further comprising: filling and smoothing oxide in the second lateral groove, and clearing epitaxial silicon at a bottom of the third groove; filling and smoothing nitride in the third groove;
the depositing a gate material within the first lateral groove and the second lateral groove comprising:
etching oxide in the first lateral groove and second lateral groove; depositing a gate material within voids of upper middle portions of the plurality of second silicon pillars, the upper middle portions comprising a gate layer and the second silicon layer; etching a gate material within a region of the second silicon layer on the plurality of second silicon pillars.

7. The method according to claim 6, after the etching a gate material within a region of the second silicon layer on the plurality of second silicon pillars, further comprising:
etching nitride of the upper middle portions of the plurality of second silicon pillars to form an air gap.

8. The method according to claim 1, before the depositing a plurality of columns of second masks on the plurality of first silicon pillars in a second direction, further comprising:
filling and smoothing oxide in gaps of the plurality of first silicon pillars.

9. An electronic device comprising a logic apparatus, wherein the logic apparatus comprises a transistor manufactured according to the method for manufacturing a transistor according to claim 1.

10. The electronic device according to claim 9, wherein the electronic device is a smart phone, a computer, a tablet computer, an artificial intelligence device, a wearable device, or a smart mobile terminal.

11. The method according to claim 2, wherein the etching the first silicon layer, the silicon germanium layer, and the second silicon layer according to the plurality of columns of second masks; continuing etching the silicon germanium layer on a basis of grooves obtained by etching; performing epitaxial growth of silicon in part of an etched region of the silicon germanium layer, depositing a gate material in a remaining etched region of the silicon germanium layer to form a plurality of second silicon pillars comprises:
etching the first silicon layer, the silicon germanium layer and the second silicon layer according to the plurality of columns of second masks to form a plurality of second grooves; performing a first lateral etching on the silicon germanium layer, and then performing a first lateral silicon epitaxy on the first silicon layer, the silicon germanium layer, and the second silicon layer to form a first lateral groove;
etching the first silicon layer, the silicon germanium layer, and the second silicon layer according to a plurality of mandrels in the plurality of second masks to form a plurality of third grooves; performing a second lateral etching on the silicon germanium layer, and then performing a second lateral silicon epitaxy on the first silicon layer, the silicon germanium layer, and the second silicon layer to form a second lateral groove, wherein two lateral etchings completely remove a silicon germanium material of the silicon germanium layer; and
depositing a gate material within the first lateral groove and the second lateral groove to form the plurality of second silicon pillars.

12. The method according to claim 3, wherein the etching the first silicon layer, the silicon germanium layer, and the second silicon layer according to the plurality of columns of second masks; continuing etching the silicon germanium layer on a basis of grooves obtained by etching; performing epitaxial growth of silicon in part of an etched region of the silicon germanium layer, depositing a gate material in a remaining etched region of the silicon germanium layer to form a plurality of second silicon pillars comprises:
etching the first silicon layer, the silicon germanium layer and the second silicon layer according to the plurality of columns of second masks to form a plurality of second grooves; performing a first lateral etching on the silicon germanium layer, and then performing a first lateral silicon epitaxy on the first silicon layer, the silicon germanium layer, and the second silicon layer to form a first lateral groove;
etching the first silicon layer, the silicon germanium layer, and the second silicon layer according to a plurality of mandrels in the plurality of second masks to form a plurality of third grooves; performing a second lateral etching on the silicon germanium layer, and then performing a second lateral silicon epitaxy on the first silicon layer, the silicon germanium layer, and the second silicon layer to form a second lateral groove, wherein two lateral etchings completely remove a silicon germanium material of the silicon germanium layer; and
depositing a gate material within the first lateral groove and the second lateral groove to form the plurality of second silicon pillars.

13. The method according to claim 4, wherein the etching the first silicon layer, the silicon germanium layer, and the second silicon layer according to the plurality of columns of second masks; continuing etching the silicon germanium layer on a basis of grooves obtained by etching; performing epitaxial growth of silicon in part of an etched region of the silicon germanium layer, depositing a gate material in a remaining etched region of the silicon germanium layer to form a plurality of second silicon pillars comprises:
etching the first silicon layer, the silicon germanium layer and the second silicon layer according to the plurality of columns of second masks to form a plurality of second grooves; performing a first lateral etching on the silicon germanium layer, and then performing a first lateral silicon epitaxy on the first silicon layer, the silicon germanium layer, and the second silicon layer to form a first lateral groove;
etching the first silicon layer, the silicon germanium layer, and the second silicon layer according to a plurality of mandrels in the plurality of second masks to form a plurality of third grooves; performing a second lateral etching on the silicon germanium layer, and then performing a second lateral silicon epitaxy on the first silicon layer, the silicon germanium layer, and the second silicon layer to form a second lateral groove, wherein two lateral etchings completely remove a silicon germanium material of the silicon germanium layer; and
depositing a gate material within the first lateral groove and the second lateral groove to form the plurality of second silicon pillars.

14. The method according to claim 2, before the depositing a plurality of columns of second masks on the plurality of first silicon pillars in a second direction, further comprising:
filling and smoothing oxide in gaps of the plurality of first silicon pillars.

15. The method according to claim 3, before the depositing a plurality of columns of second masks on the plurality of first silicon pillars in a second direction, further comprising:
filling and smoothing oxide in gaps of the plurality of first silicon pillars.

16. The method according to claim 4, before the depositing a plurality of columns of second masks on the plurality of first silicon pillars in a second direction, further comprising:
filling and smoothing oxide in gaps of the plurality of first silicon pillars.

17. An electronic device comprising a logic apparatus, wherein the logic apparatus comprises a transistor manufactured according to the method for manufacturing a transistor according to claim 2.

18. An electronic device comprising a logic apparatus, wherein the logic apparatus comprises a transistor manufactured according to the method for manufacturing a transistor according to claim 3.

19. An electronic device comprising a logic apparatus, wherein the logic apparatus comprises a transistor manufactured according to the method for manufacturing a transistor according to claim 4.

20. An electronic device comprising a logic apparatus, wherein the logic apparatus comprises a transistor manufactured according to the method for manufacturing a transistor according to claim 5.
